(19) United States
(12) Patent Application Publication
(10) Pub. No.: US 2023/0374669 A1
(43) Pub. Date: Nov. 23, 2023

(54) Wet Etching Method

(71) Applicant: Central Glass Company, Limited, Ube-shi, Yamaguchi (JP)

(72) Inventors: Kazuki YOSHIURA, Ube-shi, Yamaguchi (JP); Takuya OKADA, Ube-shi, Yamaguchi (JP); Kenta WATANABE, Ube-shi, Yamaguchi (JP); Soichi KUMON, Ube-shi, Yamaguchi (JP); Yosuke NAKAMURA, Chiyoda-ku, Tokyo (JP); Takahisa TANIGUCHI, Chiyoda-ku, Tokyo (JP)

(21) Appl. No.: 18/030,404

(22) PCT Filed: Oct. 11, 2021
(86) PCT No.: PCT/JP2021/037501

§ 371 Date: Apr. 5, 2023

(30) Foreign Application Priority Data
Oct. 16, 2020 (JP) 2020-174486

(51) Int. Cl. C23F 1/10; H01L 21/311

(52) U.S. Cl. CPC C23F 1/10; H01L 21/31111

(57) ABSTRACT

The present disclosure provides a wet etching method including pretreating a metal-containing film on a substrate with a surface modification liquid and etching the metal-containing film with an etching liquid, wherein the etching liquid is a solution containing: a β-diketone with a trifluoromethyl group bonded to a carbonyl group; and an organic solvent, wherein the metal-containing film contains a metal element capable of forming a complex with the β-diketone, wherein the surface modification liquid contains an acidic substance against the metal element, and wherein the wet etching method is carried out through: a first step of bringing the surface modification liquid into contact with the metal-containing film, thereby forming an oxide layer of the metal element at a surface of the metal-containing film; and a second step of bringing the etching liquid into contact with the metal-containing film on which the oxide layer has been formed.

### TECHNICAL FIELD

The present disclosure relates to a wet etching method and etching liquid for etching a metal-containing film on a substrate which is used in a semiconductor manufacturing process or the like.

### BACKGROUND ART

In semiconductor manufacturing processes, films of metals and of metal compounds (hereinafter occasionally referred to as metal-containing films) formed on substrates, such as metal films used as metal gate materials, electrode materials, magnetic materials etc. and metal compound films used as piezoelectric materials, LED luminescent materials, transparent electrode materials, dielectric materials etc., are processed by etching into desired patterns.

A wet etching method using a chemical liquid is known as a technique for etching a metal-containing film on a substrate in a semiconductor manufacturing process. Patent Document 1 discloses an etching method that includes providing a mixed solution of aqueous ammonia and aqueous hydrogen peroxide, with its pH being adjusted to within the range of 8 to 10 or 9 to 11, bringing the mixed solution into contact with a copper film to form a copper oxide film, and then, selectively removing the copper oxide film from the copper film by etching with the use of an acid or alkali as an etching liquid. Patent Documents 2 and 3 each disclose an etching method that uses an etching liquid containing an inorganic acid or organic acid and an oxidizing substance. Patent Document 4 discloses a method of, after etching of a metal-containing film on a substrate, smoothing a surface of the metal at an atomic level. Patent Document 5 discloses a method of selectively etching Ti with the use of an etching liquid containing an organic amine compound, a basic compound and an oxidant in an aqueous medium and having a pH of 7 to 14. Furthermore, Patent document 6 discloses an etching liquid containing a β-diketone with a trifluoromethyl group bonded to a carbonyl group and an organic solvent, as an alternative to a conventional etching liquid containing an inorganic acid, organic acid or oxidizing substance.

### PRIOR ART DOCUMENTS

### Patent Documents

Patent Document 1: Japanese Unexamined Patent Application Publication No. 2001-210630

Patent Document 2: Japanese Translation of PCT International Application No. 2008-541447

Patent Document 3: Japanese Translation of PCT International Application No. 2008-512869

Patent Document 4: Republication of PCT International Application No. 2013-161959

Patent Document 5: Japanese Unexamined Patent Application Publication No. 2013-033942

Patent Document 6: Japanese Unexamined Patent Application Publication No. 2017-028257

### SUMMARY OF THE INVENTION

The etching liquid disclosed by the present applicant in Patent Document 6 allows etching of a material containing a metal capable of forming a complex with a β-diketone, but does not allow etching of a silicon semiconductor material and a silicate glass material each of which is incapable of forming a complex with a β-diketone. The use of this disclosed etching liquid enables selective etching of only a metal-containing film against a substrate. The use of this disclosed etching liquid also enables, in the case where two or more kinds of metal-containing films are formed on a substrate, selective etching of any one of the metal-containing films against another one of the metal-containing films due to a difference in etching rate depending on the kinds of metals contained in the metal-containing films. However, the disclosed etching liquid does not attain a sufficient etching rate.

In manufacturing processes of semiconductor devices, high accuracy is required for etching techniques. When the roughness of the patterned surface of the metal-containing film after the etching becomes lamer than the roughness the surface of the metal-containing film before the etching, the characteristics of the semiconductor device can be largely influenced by such roughness. It is thus important to perform etching of the metal-containing film while maintaining small roughness of the surface of the metal-containing film.

It is accordingly an object of the present disclosure to provide a wet etching method for etching a metal-containing film on a substrate, which is used in a semiconductor manufacturing process etc., so as to perform wet etching with an improved etching rate while maintaining a small difference in roughness of the surface of the metal-containing film before and after the wet etching.

According to the present disclosure, there is provided an wet etching method comprising pretreating a metal-containing film on a substrate with a surface modification liquid and then etching the metal-containing film with an etching liquid,
wherein the etching liquid is a solution comprising a β-diketone with a trifluoromethyl group bonded to a carbonyl group and an organic solvent,
wherein the metal-containing film comprises a metal element capable of forming a complex with the β-diketone,
wherein the surface modification liquid comprises an oxidizing substance against the metal element, and
wherein the wet etching method is carried out through: a first step of bringing the surface modification liquid into contact with the metal-containing film, thereby forming an oxide layer of the metal element at a surface of the metal-containing film; and a second step of bringing the etching liquid into contact with the metal-containing film on which the oxide layer has been formed.

The wet etching method according to the present disclosure has the effect of attaining an improved etching rate while maintaining a small difference in roughness of the surface of the metal-containing film before and after the wet etching.

### BRIEF DESCRIPTION OF THE DRAWINGS

FIG. 1 is a SEM image of a surface of a Cu sample processed by the wet etching method according to the present disclosure (as Example 3).

### DETAILED DESCRIPTION OF THE EMBODIMENTS

[Wet Etching Method of Metal-Containing Film]

The wet etching method according to the present disclosure includes pretreating a metal-containing film on a substrate with the use of a surface modification liquid containing an oxidizing substance, thereby forming a layer of an oxide of the metal at a surface of the metal-containing film (as a first step), and then, etching the metal-containing film on which the oxide layer of the metal has been formed with the use of an etching liquid containing a β-diketone with a trifluoromethyl group bonded to a carbonyl group (as a second step).

The metal-containing film used as the etching target in the wet etching method of the present disclosure contains a metal element capable of forming a complex with the β-diketone. Examples of the metal element contained in the metal-containing film include Ti, Zr, Hf, V, Nb, Ta, Cr, Mo, W, Mn, Re, Fe, Ru, Os, Co, Rh, Ir, Ni, Pd, Pt, Cu, Ag, Au, Zn, Cd, Al, Ga, In, Sn, Pb and As. Each of these metal elements is capable of forming a complex with the β-diketone and is dissolved in the etching liquid by formation of a complex with the β-diketone contained in the etching liquid. Among others, Ti, Zr, Hf, V, Cr, Mn, Fe, Ru, Os, Co, Rh, Ir, Ni, Pd, Pt, Cu, Zn, Al, Ga, In, Sn, Pb and As are preferred as the metal element contained in the metal-containing film. More preferred are Ti, Zr, Hf, Cr, Fe, Ru, Co, Ni, Pt, Cu, Zn, Al, Ga, In, Sn and Pb. Particularly preferred is Cu. The metal-containing film etched by the wet etching method of the present disclosure may be a combination of a plurality of kinds of metal-containing films.

The metal-containing film is preferably any one of a film of a simple substance of one kind of metal element, a film of an alloy containing two or more kinds of metal elements and a film of a compound containing one or more kinds of metal elements. These films can be formed with small surface roughness by sputtering, chemical vapor deposition (CVD), plating or the like. Examples of the film of the alloy containing two or more kinds of metal elements include films of alloys such as NiCo, CoFe, CoPt, MnZn, NiZn, CuZn and FeNi. The alloy films may be doped with other elements as exemplified by CoFeB. Examples of the film of the compound containing the metal element or elements include films of nitrides such as GaN and AlGaN, films of silicides such as NiSi, CoSi and HfSi, films of arsenides such as InAs, GaAs and InGaAs, and films of phosphides such as InP and GaP. In the metal-containing film in which two or more kinds of elements are contained, the composition ratio of the respective elements can be set to any possible value.

In the present disclosure, there is no particular limitation on the substrate as long as the substrate is made of a material on which the metal-containing film can be formed and which does not react with the etching liquid during wet etching. Examples of the substrate include substrates of silicon semiconductor materials such as monocrystalline silicon, silicon oxide, polysilicon, silicon nitride, silicon oxynitride and silicon carbide and substrates of silicate glass materials such as soda-lime glass, borosilicate glass and quartz glass. In addition to the metal-containing film, a film of a silicon semiconductor material or the like may be provided on the substrate.

In the present disclosure, the surface modification liquid used in the pretreating step refers to a liquid capable of, by contact with the metal-containing film on the substrate, modifying an outermost surface of the metal-containing film. The term “modification” used herein means an operation for causing chemical reaction to change crystal grains and grain boundaries on the surface of the metal-containing film by the action of corrosion such that complexation in the subsequent etching step proceeds promptly.

The metal on the outermost surface of the metal-containing film may be oxidized by combination of the metal with oxygen.

In other words, the surface modification liquid can be said as a liquid capable of, by contact with the metal-containing film, forming a layer of an oxide of the metal on the outermost surface of the metal-containing film. (The term “oxidation” used herein means an operation for increasing the valence of the metal element by combination of the metal element with oxygen through chemical reaction.) In the present disclosure, the oxide layer of the metal is formed on the outermost surface of the metal-containing film by contact of the surface modification liquid with the metal-containing film.

As mentioned above, the outermost surface of the metal-containing film is converted to the oxide layer of the metal with a certain thickness in the pretreating step. In the subsequent etching step using the etching liquid containing the β-diketone with trifluoromethyl bonded to carbonyl, the oxide layer is removed by formation of a complex between the metal contained in the oxide layer and the β-diketone contained in the etching liquid. This promotes etching of the metal-containing film of certain thickness on the substrate.

The oxide layer on the outermost surface of the metal-containing film may be removed entirely or partially by treatment with the etching liquid. In the case where only a part of the oxide layer is removed by treatment with the etching liquid, it is feasible to remove the entire oxide layer by repeating the etching treatment as in the after-mentioned Examples.

Herein, a trace amount of oxygen present in the atmosphere is dissolved in the etching liquid whereby, in the case where the entire oxide layer is removed, there may occur further oxidation at the unoxidized surface of the metal-containing film by contact with the etching liquid. Hence, the etching liquid and the above-mentioned complex may be removed by, immediately after taking the substrate out of the etching liquid, rising away the etching liquid adhered to the substrate with PGMEA, IPA, water etc. and performing any drying operation such as gas blowing on the substrate. This suppresses further oxidation of the metal-containing film and keeps the surface roughness of the metal-containing film after the etching small.

Further, the surface modification liquid contains an oxidizing substance in the present disclosure. There is no particular limitation on the oxidizing substance as long as the oxidizing substance is capable of, when the surface modification liquid containing the oxidizing substance is brought into contact with the metal-containing film on the substrate, forming an oxide at the outermost surface of the metal-containing film. Specific examples of the oxidizing substance include: oxygen; ozone; peroxides such as hydrogen peroxide, dialkyl peroxide and urea hydrogen peroxide; oxidizing acids and salts thereof such as sulfuric acid, nitric acid, permanganic acid and potassium permanganate; persulfonic acids and salts thereof such as hexafluoropropanepersulfonic acid, methanepersulfonic acid, trifluoromethanepersulfonic acid and p-toluenepersulfonic acid; peracetic acid; percarbonic acid and salts thereof such as sodium percarbonate; persulfuric acid and salts thereof such as ammonium persulfate, sodium persulfate, tetramethylammonium persulfate, potassium persulfate and potassium peroxysulfate; perchloric acid and salts thereof such as sodium perchlorate, potassium perchlorate, ammonium perchlorate and tetramethylammonium perchlorate; and periodic acid and salts thereof such as periodic acid, ammonium periodate and tetramethylammonium periodate. Among others, oxygen, ozone, peroxides and oxidizing acids are preferred. Particularly preferred are oxygen, ozone, hydrogen peroxide, nitric acid and sulfuric acid.

The surface modification liquid is prepared by diluting the oxidizing substance with a solvent. The solvent for dilution of the oxidizing substance is water, any of the after-mentioned solvents, or a mixture thereof. There is no particular limitation on the solvent for dilution as long as it is capable of dissolving therein the oxidizing substance. A conventionally known solvent is usable. In view of the stability of the surface modification liquid, water is preferred as the main solvent for dilution. Herein, the main solvent refers to a solvent used in an amount of 50 wt % or more per 100 parts by weight of the diluent solvent. The amount of the oxidizing substance contained is determined depending on the relationship between the oxidizability of the metal in the metal-containing film and the oxidizability of the oxidizing substance. In view of the length of time for contact of the surface modification liquid and the effect for improving the roughness of the metal-containing film after the wet etching, the amount of the oxidizing substance contained is preferably 0.01 to 50 mass %, more preferably 0.02 to 20 mass %, still more preferably 0.05 to 10 mass %, per 100 parts by mass of the surface modification liquid.

In the present disclosure, the etching liquid is a solution containing a β-ketone with a trifluoromethyl group bonded to a carbonyl group and an organic solvent. In comparison with a β-diketone in which trifluoromethyl is not bonded to carbonyl, the β-ketone in which trifluoromethyl (CF₃) is bonded to carbonyl (C═O) enables rapid etching and is less likely to cause aggregation of a complex thereof with the metal and less likely to cause solid deposition. There is no particular limitation on the β-diketone contained in the etching liquid as long as the β-diketone has a moiety in which trifluoromethyl (CF₃) is bonded to carbonyl (C═O). The β-diketone is preferably one kind, or a combination of two or more kinds, selected from the group consisting of hexafluoroacetylacetone (1,1,1,5,5,5-hexafluoro-2,4-pentanedione; occasionally referred to as “HFAc” in the present specification), trifluoroacetylacetone (1,1,1-trifluoro-2,4-pentanedione), 1,1,1,6,6,6-hexafluoro-2,4-hexanedione, 4,4,4-trifluoro-1-(2-thienyl)-1,3-butanedione, 4,4,4-trifluoro-1-phenyl-1,3-butanedione, 1,1,1,5,5,5-hexafluoro-3-methyl-2,4-pentanedione, 1,1,1,3,5,5,5-heptafluoro-2,4-pentanedione and 1,1,1-trifluoro-5,5-dimethyl-2,4-hexanedione. Particularly preferred is hexafluoroacetylacetone.

There is no particular limitation on the organic solvent contained in the etching liquid as long as the organic solvent is capable of dissolving therein the β-diketone and causes less damage on the surface of the processing target. A conventionally known organic solvent is usable. For example, there can be used an alcohol, a hydrocarbon, an ester, an ether, a ketone, a halogen-containing solvent, a sulfoxide, a lactone, a carbonate, a polyalcohol derivative, a nitrogen-containing solvent, a silicone, or a mixed solvent thereof. Among others, a hydrocarbon, an ester, an ether, a halogen-containing solvent, a polyol derivative without OH group or a mixed solvent thereof is preferably used because the use of such a solvent leads to good stability of the etching liquid.

Examples of the alcohol include methanol, ethanol, 1-propanol, 2-propanol, 1-butanol, 2-butanol, isobutanol, tert-butanol, 1-pentanol, 2-pentanol, 3-pentanol, 2-methyl-1-butanol, 3-methyl-1-butanol, 2-methyl-2-butanol, 3-methyl-2-butanol, 1-hexanol, 2-hexanol, 3-hexanol, 2-methyl-1-pentanol, 3-methyl-1-pentanol, 4-methyl-1-pentanol, 2-methyl-2-pentanol, 3-methyl-2-pentanol, 4-methyl-2-pentanol, 2-methyl-3-pentanol, 3-methyl-3-pentanol, 2,2-dimethyl-1-butanol, 3,3-dimethyl-1-butanol, 3,3-dimethyl-2-butanol, 2-ethyl-1-butanol, 1-heptanol, 2-heptanol, 3-heptanol, 4-heptanol, benzylalcohol, 1-octanol, isooctanol and 2-ethyl-1-hexanol.

Examples of the hydrocarbon include n-hexane, n-heptane, n-octane, n-nonane, n-decane, n-undecane, n-dodecane, n-tetradecane, n-hexadecane, n-octadecane, n-icosane, branched hydrocarbons of corresponding carbon numbers (as exemplified by isododecane, isocetane etc.), cyclohexane, methylcyclohexane, decalin, benzene, toluene, xylene, (ortho-, meta- or para-)diethylbenzene, 1,3,5-trimethylbenzene and naphthalene.

Examples of the ester include ethyl acetate, n-propyl acetate, i-propyl acetate, n-butyl acetate, i-butyl acetate, n-pentyl acetate, i-pentyl acetate, n-hexyl acetate, n-heptyl acetate, n-octyl acetate, n-pentyl formate, n-butyl propionate, ethyl butyrate, n-propyl butyrate, i-propyl butyrate, n-butyl butyrate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate, methyl 3-methoxypropionate, ethyl 3-methoxypropionate, methyl 3-ethoxypropionate, ethyl 3-ethoxypropionate and ethyl ethoxyacetate.

Examples of the ether include di-n-propyl ether, ethyl-n-butyl ether, di-n-butyl ether, ethyl-n-amyl ether, di-n-amyl ether, ethyl-n-hexyl ether, di-n-hexyl ether, di-n-octyl ether, ethers with branched hydrocarbon groups of corresponding carbon numbers (as exemplified by diisopropyl ether, diisoamyl ether etc.), dimethyl ether, methyl ethyl ether, methyl cyclopentyl ether, diphenyl ether, tetrahydrofuran, dioxane, methyl perfluoropropyl ether, methyl perfluorobutyl ether, ethyl perfluorobutyl ether, methyl perfluorohexyl ether and ethyl perfluorohexyl ether.

Examples of the ketone include acetone, acetylacetone, methyl ethyl ketone, methyl propyl ketone, methyl butyl ketone, 2-heptanone, 3-heptanone, cyclohexanone and isophorone.

Examples of the halogen-containing solvent include: perfluorocarbons such as perfluorooctane, perfluorononane, perfluorocyclopentane, perfluorocyclohexane and perfluorobenzene; hydrofluorocarbons such as 1,1,1,3,3-pentafluorobutane, octafluorocyclopentane, 2,3-dihydrodecafluoropentane and Zeorora H (manufactured by Nippon Zeon Co., Ltd.); hydrofluoroethers such as methyl perfluoroisobutyl ether, methyl perfluorobutyl ether, ethyl perfluorobutyl ether, ethyl perfluoroisobutyl ether, Asahiklin AE-3000 (manufactured by AGC Inc.), Novec 7100, Novec 7200, Novec 7300 and Novec 7600 (each manufactured by 3M Company); chlorocarbons such as tetrachloromethane; hydrochlorocarbons such as chloroform; chlorofluorocarbons such as dichlorodifluoromethane; hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene and 1,2-dichloro-3,3,3-trifluoropropane; perfluoroethers; and perfluoropolyethers.

Examples of the sulfoxide include dimethyl sulfoxide.

Examples of the lactone include β-propiolactone, γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone and ε-hexanolactone.

Examples of the carbonate include dimethyl carbonate, ethyl methyl carbonate, diethyl carbonate and propylene carbonate.

Examples of the polyalcohol derivative include ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether, diethylene glycol monobutyl ether, triethylene glycol monomethyl ether, triethylene glycol monoethyl ether, triethylene glycol monopropyl ether, triethylene glycol monobutyl ether, tetraethylene glycol monomethyl ether, tetraethylene glycol monoethyl ether, tetraethylene glycol monopropyl ether, tetraethylene glycol monobutyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tripropylene glycol monoethyl ether, tripropylene glycol monopropyl ether, tripropylene glycol monobutyl ether, tetrapropylene glycol monomethyl ether, butylene glycol monomethyl ether, ethylene glycol dimethyl ether, ethylene glycol diethyl ether, ethylene glycol dibutyl ether, ethylene glycol monomethyl ether acetate, ethylene glycol monoethyl ether acetate, ethylene glycol monobutyl ether acetate, ethylene glycol diacetate, diethylene glycol dimethyl ether, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol dibutyl ether, propylene glycol monomethyl ether acetate (PGMEA), propylene glycol monoethyl ether acetate, propylene glycol monobutyl ether acetate, propylene glycol diacetate, dipropylene glycol dimethyl ether, dipropylene glycol methyl propyl ether, dipropylene glycol diethyl ether, dipropylene glycol dibutyl ether, dipropylene glycol monomethyl ether acetate, dipropylene glycol monoethyl ether acetate, dipropylene glycol monobutyl ether acetate, dipropyelen glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol dimethyl ether, butylene glycol monomethyl ether acetate, butylene glycol diacetate and glycerin triacetate.

Examples of the nitrogen-containing solvent include formamide, N,N-dimethylformamide, N,N-dimethylacetamide, N-diethylacetamide, N-methyl-2-pyrrolidone, N-ethyl-2-pyrrolidone, N-propyl-2-pyrrolidone, 1,3-dimethyl-2-imidazolidinone, 1,3-diethyl-2-imidazolidinone, 1,3-diisopropyl-2-imidazolidinone, alkylamine, dialkylamine, trialkylamine and pyridine.

Examples of the silicone include hexamethyldisiloxane, octamethyltrisiloxane, decamethyltetrasiloxane and dodecamethylpentasiloxane.

In view of the stability of the etching liquid, it is preferable to select the organic solvent from hydrocarbons, esters, ethers, halogen-containing solvents, carbonates and polyalcohols without OH groups. Among others, esters, ethers and polyalcohols without OH groups are preferred in view of the cost and environmental load. Propylene glycol monoalkyl ether acetate is more preferred. Particularly preferred is propylene glycol monomethyl ether acetate.

The β-diketone, when converted to a hydrate, tends to be deposited as a solid. Thus, the amount of water contained in the etching liquid is preferably 20 mass % or less, more preferably 10 mass % or less, still more preferably 1 mass % or less, per 100 parts by mass of the etching liquid.

Further, the concentration of the β-diketone in the etching liquid is preferably 0.5 to 15 mass %, more preferably 1 to 12 mass %, still more preferably 2 to 10 mass %. Since the β-diketone is generally more expensive than the organic solvent, the etching liquid becomes too expensive when the concentration of the β-diketone is too high. In addition, there is a tendency that the roughness of the metal-containing film becomes deteriorated when the concentration of the β-diketone is higher than 10 mass %. On the other hand, there is a tendency that the etching does not proceed when the concentration of the β-diketone is lower than 1 mass %.

For improvements of etching rate and etching selectivity, an additive such as citric acid, formic acid, acetic acid, trifluoroacetic acid etc. may be added into the etching liquid as long as the processing target is not adversely affected by the additive.

The amount of the additive contained in the etching liquid is adjusted within the range that does not adversely affect the processing target. For example, the additive can be contained in an amount of 0.01 to 20 mass %, preferably 0.1 to 15 mass %, more preferably 0.5 to 10 mass %, relative to the etching liquid. The etching liquid may substantially consist of the β-diketone with trifluoromethyl bonded to carbonyl and the organic solvent.

The wet etching method of the present disclosure enables etching of the metal-containing film, without causing an increase of the roughness of the metal-containing film, through the first step of bringing the surface modification liquid into contact with the metal-containing film and the second step of bringing the etching liquid into contact with the metal-containing film modified by contact with the surface modification liquid. In the wet etching method, the metal-containing film can be wet-etched by introducing the surface modification liquid and/or etching liquid into any device such as etching device in which the substrate having the metal-containing film as the processing target is placed and thereby bringing the surface modification liquid and/or etching liquid into contact with the metal-containing film of the processing target.

In the wet etching method of the present disclosure, there is no particular limitation on the type and system of the device for application of the surface modification liquid and/or etching liquid as long as the device is configured to hold the liquid. For example, there can be used a single substrate processing system using a spin device capable of processing substrates one by one by rotating the substrate in a nearly horizontal position while supplying the liquid to the vicinity of the rotation center of the substrate or a batch system using a device capable of processing a plurality of substrates together by immersing the substrates in the liquid within a chamber.

There is also no particular limitation on the form of the etching liquid supplied to the surface of the processing target as long as the etching liquid is in a liquid state when held on the processing target. For example, the etching liquid can be supplied in liquid form or vapor form.

The first step and the second step are not necessarily performed continuously. It is preferable to, between the first step and the second step, perform a rinsing step of rinsing the surface of the metal-containing film to which the surface modification liquid has been adhered. The rinsing step leads to a reduction in the amount of the oxidizing substance contained in the etching liquid so that it is possible to prevent the oxidizing substance from being brought into contact with the metal-containing film.

One example of the rinsing step is to remove the oxidizing substance from the metal-containing film by bringing water, an organic solvent or the like into contact with the metal-containing film. There is no particular limitation on the organic solvent used in the rinsing step as long as the organic solvent is capable of dissolving the etching liquid and/or the oxidizing substance. A conventionally known organic solvent is usable. Examples of the organic solvent usable in the rising step are the same as those usable in the etching liquid. In view of the solubility of the surface modification liquid, it is preferable to use any of water, alcohols and polyol derivatives. It is also preferable to use the same solvent as that used in the surface treatment liquid. In the rinsing step, a plurality of times of rinsing may be performed with the use of water or organic solvent. For example, it is feasible to perform rinsing with the same solvent as that used in the surface modification liquid and then perform rinsing with the same solvent as that used in the etching liquid. This rising operation is preferable when the solvent contained in the surface modification liquid is reactive with the β-diketone contained in the etching liquid.

In the case where the solvent used in the surface modification liquid is not compatible with the solvent used in the etching liquid, it is a preferable embodiment to rinse the metal-containing film with any solvent compatible with both of the solvent used in the surface modification liquid and the solvent used in the etching liquid. For example, it is preferable to bring the metal-containing film into contact with the surface modification liquid, rinse the metal-containing film with ultrapure water, 2-propanol or propylene glycol-1-monomethyl ether-2-acetate, and then, bring the metal-containing film into contact with the etching liquid as in the after-mentioned Examples.

The first step and the second step can be executed repeatedly. The repeated execution of the first and second steps leads to an improvement of etching amount without causing a deterioration of surface roughness.

In the case where the first and second steps are executed repeatedly, it is a preferable embodiment to rinse with propylene glycol-1-monomethyl ether-2-acetate, 2-propanol or ultrapure water etc. the substrate taken out after the contact with the etching liquid, and then, bring the substrate into contact with the surface modification liquid.

In the present disclosure, the amount of the oxidizing substance contained in the etching liquid is preferably 0.01 mass % or less, more preferably 0.005 mass % or less, per 100 parts by mass of the etching liquid. When the amount of the oxidizing substance contained in the etching liquid is in the aforementioned range, the rinsing step is not necessarily performed between the first and second steps to rinse the surface of the metal-containing film to which the surface modification liquid has been attached. By performing the rinsing step in such a manner as to adjust the amount of the oxidizing substance to 0.001 mass % or less, however, it is possible to minimize the roughness of the surface of the metal-containing film after the etching.

In order to prevent the oxidizing substance contained in the etching liquid from being brought into contact with the metal-containing film in the second step, it is preferable to perform repeated times of rinsing until the amount of the oxidizing substance contained in the etching liquid reaches 0 mass %. In order to perform the rinsing step efficiently, the lower limit of the amount of the oxidizing substance contained in the etching liquid may be a detection limit value. Alternatively, the lower limit of the amount of the oxidizing substance contained in the etching liquid may be set to 0.0001 mass % so as to perform the rinsing in such a manner that the amount of the oxidizing substance contained in the etching liquid ranges from 0.0001 mass % to 0.001 mass %. When the amount of the oxidizing substance contained in the etching liquid exceeds 0.01 mass % per 100 parts by mass of the etching liquid, it may become difficult to decrease a difference in roughness of the surface of the metal-containing film before and after the etching.

The metal-containing film may be, before the first step, treated by contact with an etchant capable of etching the metal-containing film. There are cases where the outermost surface of the metal-containing film has been naturally oxidized under the influence of any process step prior to the treatment with the surface modification liquid or under the influence of air contact. It is thus preferable to perform a step of treating the metal-containing film by contact with the etchant in advance because the natural oxide is removed from the outermost surface of the metal-containing film by this etchant contact step. The etching liquid used in the second step is applicable as the etchant in the etchant contact step.

In the wet etching method of the present disclosure, there is no particular limitation on the temperature of the surface modification liquid as long as the surface modification liquid is maintained in a liquid state. In view of the length of time for contact of the surface modification liquid with the metal-containing film and the roughness of the metal-containing film after the etching, the temperature of the surface modification liquid is set as appropriate within the range of about −10 to 60° C.

There is also no particular limitation on the temperature of the etching liquid as long as the etching liquid is maintained in a liquid state. In view of the length of time for contact of the etching liquid with the metal-containing film and the roughness of the metal-containing film after the etching, the temperature of the etching liquid is set as appropriate within the range of about −10 to 100° C.

There is no particular limitation on the length of time for contact of the surface modification liquid with the metal-containing film. In view of the efficiency of semiconductor manufacturing process, the time for contact of the surface modification liquid is preferably 60 minutes or less, more preferably 10 minutes or less, still more preferably 2 minutes or less.

Further, there is no particular limitation on the length of time for contact of the etching liquid with the metal-containing film. In view of the efficiency of semiconductor manufacturing process, the time of contact of the etching liquid is preferably 60 minutes or less, more preferably 10 minutes or less, still more preferably 2 minutes or less. Herein, the length of time for contact of the surface modification liquid or etching liquid refers to e.g. a period of time during which the liquid is ejected to the processing target substrate, a period of time during which the processing target substrate is immersed in the liquid, or a period of time from the introduction of the etching liquid into the process chamber in which the substrate is placed until the discharge of the etching liquid out of the process chamber for completion of the etching.

The wet etching method of the present disclosure enables etching of the target metal-containing film, without etching a non-target substrate that does not contain a metal element capable of forming a complex with the β-diketone, or a film of silicon semiconductor material. The wet etching method of the present disclosure also allows an improvement in roughness of the metal-containing film after the etching with the use of a wet etching device, which is inexpensive as compared to a dry etching device, so as to thereby lead to an improvement of semiconductor device quality.

[Device]

By adopting the wet etching method of the present disclosure, it is possible to manufacture high-performance devices. The devices can be manufactured at low cost with the use of metal-containing films etched by the wet etching method of the present disclosure. Examples of such devices include solar batteries, hard disk drives, locked IC, dynamic random access memories, phase change random access memories, ferroelectric random access memories, magneto-resistive random access memories, resistive random access memories, MEMS and the like.

### EXAMPLES

The present invention will be described in more detail below by way of the following examples. It should however be understood that the present invention is not limited to those examples.

Hereinafter, an explanation will now be given of evaluation methods, liquid preparation processes, etching processes and evaluation results.

[Evaluation Methods]

(Measurement of Etching Amount)

An etching amount of a metal-containing film on a substrate was determined based on a change of the mass of the substrate before and after immersion of the substrate into an etching liquid. Herein, the specific gravity of Cu used as the metal-containing film was taken as 8.94 g/cm³. An etching rate of the metal-containing film was determined by “etching amount [nm]/immersion time [sec]”.

(Measurement of Surface Roughness)

A surface of a metal-containing film was measured with an AFM system (available as SHIMADZU SPM-9700, scanning range: 1.00 μm, scanning speed: 1.0 Hz) before etching (i.e. in an initial state) and after etching. An arithmetic mean roughness Ra (nm) of the surface of the metal-containing film was determined based on the measurement result. Then, a difference of Ra (ΔRa) before and after the etching was calculated from the determination results. Herein, Ra refers to a three-dimensional extension of a center line average roughness applied to a measurement surface as defined in JIS B 0601 and determined as the “average of absolute values of deviations from a reference plan to a designated plane” according to the following equation.

$$Ra = \frac{1}{{S}_{0}} {\int }_{{Y}_{T}}^{{Y}_{B}} {\int }_{{X}_{L}}^{{X}_{R}} \vert F ( X , Y ) - {Z}_{0} \vert dXdY$$

In the above equation, X_{L}, X_{R}, Y_{B} and Y_{T} represent measurement ranges of X and Y coordinates, respectively; So represents an area of the measurement surface, assuming that the measurement surface has a theoretically flat profile, as given by (X_{R}−X_{L})×(Y_{B}−Y_{T}); F(X, Y) represents a height of the measurement point (X, Y); and Zo represents an average height in the measurement surface.

(Observation of Surface Shape)

A surface shape of a metal-containing film was observed with a SEM system (available as SU8010 from Hitachi Ltd., acceleration voltage: 10.0 kV, emission current: 20 pA).

### Example 1

(Preparation of Liquids)

A surface modification liquid was prepared by mixing aqueous hydrogen peroxide and ultrapure water (H₂O) such that the concentration of hydrogen peroxide became 1 mass %. Further, an etching liquid was prepared by mixing hexafluoroacetylacetone (HFAc) and propylene glycol-1-monomethyl ether-2-acetate (PGMEA) as a solvent such that the concentration of HFAc became 5 mass %. Herein, the content of water in the etching liquid was 1 mass % or less.

(Wet Etching Process)

As a processing target, provided was a silicon substrate having a Cu film (thickness: 1 μm, arithmetic mean surface roughness Ra: 6 μm) formed as a metal-containing film by a plating technique. A pretreating step was performed on the substrate by immersing the substrate in the above-prepared surface modification liquid at 24° C. for 20 seconds, whereby an oxide layer was formed at an outermost surface of the Cu film. The surface modification liquid adhered to the surface of the substrate was rinsed away. This rinsing step was performed by immersing the substrate in each of ultrapure water, 2-propanol (IPA) and then PGMEA at 24° C. for 20 seconds. An etching step was subsequently performed on the substrate by immersing the substrate in the above-prepared etching liquid at 24° C. for 20 seconds. The etching liquid adhered to the surface of the substrate was rinsed away. This rinsing step was also performed by immersing the substrate in each of PGMEA, IPA and then ultrapure water at 24° C. for 20 seconds. Finally, the surface of the substrate was dried by gas blowing for 10 seconds.

### Examples 2 to 4

A surface modification liquid and an etching liquid were prepared in the same manner as in Example 1. As a processing target, provided was a silicon substrate the same type of as that used in Example 1. Wet etching process was performed on the substrate in the same manner as in Example 1, except that a series of pretreating, rinsing, etching and rinsing steps was repeated two times, five times or ten times.

### Example 5

A surface modification liquid and an etching liquid were prepared in the same manner as in Example 1. Provided was a silicon substrate the same type of as that used in Example 1. Before immersion in the surface modification liquid, the substrate was immersed in the etching liquid at 24° C. for 20 seconds. The etching liquid adhered to the surface of the substrate was rinsed away by immersing the substrate in each of PGMEA IPA and ultrapure water at 24° C. for 20 seconds. After that, wet etching process was performed on the substrate in the same manner as in Example 1.

### Example 6

A surface modification liquid was prepared in the same manner as in Example 1. An etching liquid was prepared in the same manner as in Example 1, except that propylene glycol monomethyl ether (PGME) was used as the solvent. Provided was a silicon substrate of the same type as that used in Example 1. Wet etching process was performed on the substrate as follows. The substrate was first immersed in the surface modification liquid at 24° C. for 20 seconds. Without rinsing the surface of the substrate, the substrate was immersed in the etching liquid at 24° C. for 20 seconds with the surface modification liquid being adhered to the surface of the substrate. This etching process operation was repeated ten times. Then, the etching liquid adhered to the surface of the substrate was rinsed away by immersing the substrate in each of PGME, IPA and ultrapure water at 24° C. for 20 seconds. Finally, the surface of the substrate was dried by gas blowing for 10 seconds.

### Comparative Example 1

An etching liquid was prepared in the same manner as in Example 1. Provided was a silicon substrate of the same type as that used in Example 1. Wet etching process was performed on the substrate in the same manner as in Example 1, except that the substrate was immersed in the etching liquid at 24° C. for 20 seconds, immersed in each of PGMEA and 2-propanol (IPA) at 24° C. for 20 seconds and then dried by gas blowing for 10 seconds. In other words, the pretreating step in which the substrate was immersed in the surface modification liquid was omitted in this Comparative Example.

### Comparative Example 2

Wet etching process was performed in the same manner as in Comparative Example 1, except that the etching step was performed by immersing the substrate in the etching liquid at 24° C. for 40 seconds.

### Comparative Example 3

Wet etching process was performed in the same manner as in Comparative Example 1, except that the etching step was performed by immersing the substrate in the etching liquid at 24° C. for 80 seconds.

### Comparative Example 4

Wet etching process was performed in the same manner as in Comparative Example 1, except that the etching liquid was prepared by mixing 98 mass % sulfuric acid and IPA such that the concentration of sulfuric acid in the etching liquid was 5 mass %.

### Comparative Example 5

Wet etching process was performed in the same manner as in Comparative Example 1, except that the etching liquid was prepared by mixing 25% aqueous ammonia and IPA such that the concentration of NH₃ in the etching liquid was 2 mass %.

### Comparative Example 6

Wet etching process was performed in the same manner as in Comparative Example 5, except that the etching step was performed by immersing the substrate in the etching liquid at 24° C. for 40 seconds.

### Comparative Example 7

Wet etching process was performed in the same manner as in Comparative Example 5, except that the etching step was performed by immersing the substrate in the etching liquid at 24° C. for 80 seconds.

<Etching Amount [nm] and ΔRa [nm>

The results of Examples 1 to 6 and Comparative Examples 1 to 3 are shown in TABLES 1 and 2. It has been shown by these results that the etching method of the present disclosure enables etching of the metal-containing film that contains a predetermined metal element, with an improved etching rate, while suppressing an increase of ΔRa. It has also been shown that the etching method of the present disclosure allows an increase of etching amount according to the number of times of repetition of etching process and can suppress an increase of ΔRa even with increase of etching amount.

There was seen a significant increase of ΔRa in each of Comparative Examples 4 to 7 in which an acid or base was used in the etching liquid without using a β-diketone.

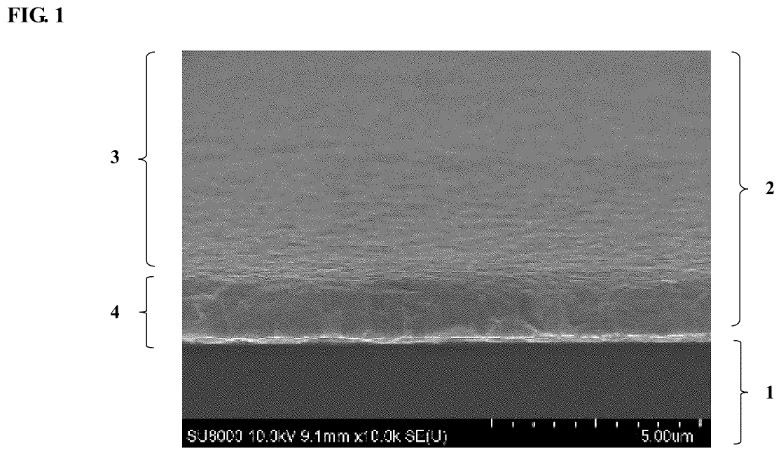

FIG. 1 shows a SEM image of the surface of the Cu film after five times of the etching process in Example 3. As shown in this FIGURE, the surface of the Cu film after the etching was smooth and did not show large roughness in Example 3.

In Examples 1 to 5, the surface roughness of the metal-containing film after the etching showed no large difference from the surface roughness of the Cu film provided as the metal-containing film before the contact of the surface modification liquid with the metal-containing film and from the surface roughness of the surficial oxide layer of the Cu film before the etching. The surface roughness of the metal-containing film after the etching was smaller in Examples 1 to 5 in each of which the surface modification liquid was rinsed away by the rinsing step than in Example 6 in which the surface modification liquid was not rinsed away by the rinsing step.

TABLE 1

| | Metal- | Surface Modification Liquid | | | | Etching Liquid | | | | | |
|---|---|---|---|---|---|---|---|---|---|---|---|
| | Containing | Peroxide | | | Immersion | β-Diketone | | | Others | | Immersion |
| | Film | Kind | Conc. | Solvent | Time [sec] | Kind | Conc. | Solvent | Kind | Conc. | Time [sec] |
| Example 1 | Cu | H₂O₂ | 1 mass % | H₂O | 20 | HFAc | 5 mass % | PGMEA | — | — | 20 |
| Example 2 | Cu | H₂O₂ | 1 mass % | H₂O | 20 | HFAc | 5 mass % | PGMEA | — | — | 20 |
| Example 3 | Cu | H₂O₂ | 1 mass % | H₂O | 20 | HFAc | 5 mass % | PGMEA | — | — | 20 |
| Example 4 | Cu | H₂O₂ | 1 mass % | H₂O | 20 | HFAc | 5 mass % | PGMEA | — | — | 20 |
| Example 5 | Cu | H₂O₂ | 1 mass % | H₂O | 20 | HFAc | 5 mass % | PGMEA | — | — | 20 |
| Example 6 | Cu | H₂O₂ | 1 mass % | H₂O | 20 | HFAc | 5 mass % | PGME | — | — | 20 |
| Comparative | Cu | — | — | — | — | HFAc | 5 mass % | PGMEA | — | — | 20 |
| Example 1 | | | | | | | | | | | |
| Comparative | Cu | — | — | — | — | HFAc | 5 mass % | PGMEA | — | — | 40 |
| Example 2 | | | | | | | | | | | |
| Comparative | Cu | — | — | — | — | HFAc | 5 mass % | PGMEA | — | — | 80 |
| Example 3 | | | | | | | | | | | |
| Comparative | Cu | H₂O₂ | 1 mass % | H₂O | 20 | — | — | IPA/H₂O | H₂SO₄ | 5 mass % | 20 |
| Example 4 | | | | | | | | | | | |
| Comparative | Cu | H₂O₂ | 1 mass % | H₂O | 20 | — | — | IPA/H₂O | NH₃ | 2 mass % | 20 |
| Example 5 | | | | | | | | | | | |
| Comparative | Cu | H₂O₂ | 1 mass % | H₂O | 20 | — | — | IPA/H₂O | NH₃ | 2 mass % | 40 |
| Example 6 | | | | | | | | | | | |
| Comparative | Cu | H₂O₂ | 1 mass % | H₂O | 20 | — | — | IPA/H₂O | NH₃ | 2 mass % | 80 |
| Example 7 | | | | | | | | | | | |

TABLE 2

| | | | | Surface Roughness | | |
|---|---|---|---|---|---|---|
| | | Rinsing Between | Etching | Ra [nm] | | |
| | | Pretreating | Amount | Before | After | ΔRa |
| | Order of Process Steps | and Etching | [nm] | Etching | Etching | [nm] |
| Example 1 | Pretreating → Etching | Done | 6 | 6 | 5 | −1 |
| Example 2 | (Pretreating → Etching) × 2 | Done | 14 | 6 | 5 | −1 |
| Example 3 | (Pretreating → Etching) × 5 | Done | 26 | 6 | 6 | 0 |
| Example 4 | (Pretreating → Etching} × 10 | Done | 45 | 6 | 6 | 0 |
| Example 5 | Etching → Pretreating → | Done | 12 | 6 | 5 | −1 |
| | Etching | | | | | |
| Example 6 | (Pretreating → Etching) × 10 | Not Done | 29 | 6 | 9 | 3 |
| Comparative | Etching | — | 0 | 6 | 5 | −1 |
| Example 1 | | | | | | |
| Comparative | Etching | — | 1 | 6 | 6 | 0 |
| Example 2 | | | | | | |
| Comparative | Etching | — | 1 | 6 | 6 | 0 |
| Example 3 | | | | | | |
| Comparative | Pretreating → Etching | Done | 30 | 6 | 18 | 12 |
| Example 4 | | | | | | |
| Comparative | Pretreating → Etching | Done | 3 | 6 | 17 | 11 |
| Example 5 | | | | | | |
| Comparative | Pretreating → Etching | Done | 7 | 6 | 19 | 13 |
| Example 6 | | | | | | |
| Comparative | Pretreating → Etching | Done | 15 | 6 | 25 | 19 |
| Example 7 | | | | | | |

### DESCRIPTION OF REFERENCE NUMERALS

1: Substrate
2: Metal-containing Film
3: Surface (Roughness Side) of Metal-Containing Film
4: Cross Section of Metal-Containing Film

1. A wet etching method comprising pretreating a metal-containing film on a substrate with a surface modification liquid and then etching the metal-containing film with an etching liquid,
wherein the etching liquid is a solution comprising: a b-diketone with a trifluoromethyl group bonded to a carbonyl group; and an organic solvent,
wherein the metal-containing film comprises a metal element capable of forming a complex with the b-diketone,
wherein the surface modification liquid comprises an acidic substance against the metal element, and
wherein the wet etching method is carried out through: a first step of bringing the surface modification liquid into contact with the metal-containing film, thereby forming an oxide layer of the metal element at a surface of the metal-containing film; and a second step of bringing the etching liquid into contact with the metal-containing film on which the oxide layer has been formed.

2. The wet etching method according to claim 1,
wherein the acidic substance is not brought into contact with the metal-containing film in the second step.

3. The wet etching method according to claim 1,
wherein the wet etching method comprises, between the first step and the second step, rinsing a surface of the substrate.

4. The wet etching method according to claim 1,
wherein a time for contact of the metal-containing film with the surface modification liquid is 2 minutes or less, and
wherein a time for contact of the metal-containing film with the etching liquid is 2 minutes or less.

5. The wet etching method according to claim 1,
wherein a concentration of the b-diketone in the etching liquid is 0.5 to 15 mass %.

6. The wet etching method according to claim 1,
wherein the acidic substance is not contained in the etching liquid in an amount of 0.01 mass % or more per 100 parts by mass of the etching liquid.

7. The wet etching method according to claim 1,
wherein the acidic substance is at least one kind selected from the group consisting of oxygen, ozone, peroxides, oxidizing acids and salts thereof, persulfonic acids and salts thereof, peracetic acid, percarbonic acid and salts thereof, persulfuric acid and salts thereof, perchloric acid and salts thereof, and periodic acid and salts thereof.

8. The wet etching method according to claim 1,
wherein the acidic substance is at least one kind selected from the group consisting of oxygen, ozone, hydrogen peroxide, nitric acid, and sulfuric acid.

9. The wet etching method according to claim 1,
wherein an amount of the acidic substance contained in the surface modification liquid is 0.01 to 20 mass % per 100 parts by weight of the surface modification liquid.

10. The wet etching method according to claim 1, wherein a material of the substrate is a silicon semiconductor material or a silicate glass material.
